(19) United States
(12) Patent Application Publication
(10) Pub. No.: US 2026/0274653 A1
(43) Pub. Date: Sep. 17, 2026

(54) Deformation Bonded and Hermetically Sealed Vacuum MEMS Cells with Stopping Layer

(71) Applicant: HRL Laboratories, LLC, Malibu, CA (US)

(72) Inventors: Travis M. Autry, Malibu, CA (US); Megan Kelleher, Malibu, CA (US); Peter D. Brewer, Malibu, CA (US); Lianxin Huang, Malibu, CA (US)

(73) Assignee: HRL Laboratories, LLC, Malibu, CA (US)

(21) Appl. No.: 19/658,377

(22) Filed: Apr. 24, 2026

Related U.S. Application Data
(63) Continuation-in-part of application No. 18/904,886, filed on Oct. 2, 2024.
(60) Provisional application No. 63/918,022, filed on Nov. 14, 2025.

(51) Int. Cl. B81C 1/00; B81B 7/00

(52) U.S. Cl. CPC B81C 1/00285; B81B 7/0038; B81B 2207/056; B81C 2203/019; B81C 2203/07

(57) ABSTRACT

A micro-vacuum cell comprising at least one vacuum enclosure with a lid of a first material and a base of a second material, the first and second material having a different coefficients of thermal expansion, where the vacuum enclosure is formed above a portion of the base; a cold weld compression seal attaches the lid to the base along a periphery of said portion of the base; wherein the cold weld compression seal comprises a peripheral knife-edge wall with a foot being attached to one of the lid and the base and a tip that penetrates seal layer arranged on the other of the lid and the base; and a stop structure, shorter than the knife edge wall, with a foot attached to the same surface as the knife-edge wall and a tip that forms a compression bond with the seal layer.

### CROSS REFERENCE TO RELATED APPLICATIONS

This application is a continuation-in-parts application claiming priority to US Patent Application Serial No. 18/904886 filed Oct. 2, 2024 and entitled “High-Vacuum Micro-Vacuum Cells”, the disclosures of which are hereby incorporated herein by reference. This application claims priority of US provisional application No. 63/918022, filed on Nov. 14, 2025 and entitled “Deformation Bonded and Hermetically Sealed Vacuum MEMS Cells with Stopping Layer”, the disclosures of which are hereby incorporated herein by reference.

### STATEMENT REGARDING FEDERALLY SPONSORED RESEARCH OR DEVELOPMENT

This invention was made with government support under contract number HR0011-23-C-0042 awarded by DARPA. The government has certain rights in the invention.

### TECHNICAL FIELD

This presentation relates to Micro-Vacuum Cells (MVC) for Micro-Electro Mechanical Systems (MEMS) and Chip-Scale Atomic Systems (CSAS), in particular to apparatuses comprising a vacuum enclosure. This presentation also relates to methods of manufacturing such micro-vacuum cells or apparatuses.

### BACKGROUND

MVC (Micro-Vacuum Cells) comprise very small devices incorporating some combination of atomic, electronic, photonic and moving parts. MVCs may contain MEMS or CSAS sensors or devices (micro-mirrors, mechanical oscillators, ion-traps, mass spectrometers, or thermal gasses of atoms) having a size of the order of a micrometer. MVC may comprise a processing unit that processes data (for example an integrated circuit chip such as a microprocessor) and at least one component that interacts with the processing unit. Due to their sensitivity to the ambient environment, the MEMS and CSAS devices are generally enclosed in a vacuum enclosure, preferably with a high degree of vacuum for high quality and performance, thus making the MEMS and CSAS part of a MVC.

MEMS and CSAC devices having high vacuum enclosures are for example required for a variety of navigation and timing devices that include gyroscopes, quartz oscillators, integrated photonic devices, optical cavities, quantum sensors and atomic clocks. It is known to manufacture MVC vacuum enclosures using anodic, eutectic and thermocompression bonding of die and wafer level packages. However, an anodic bonding process releases undesirable gasses such as O₂ which contaminates the inside of the vacuum enclosure. Eutetic, thermocompression, glass-frit, diffusion, and anodic bonding generally require bonding at high temperatures (hereafter a temperature > 250C) where material outgassing becomes a problem during the bonding process by also contaminating the inside of the vacuum enclosure. It is known to provide the inside of a vacuum enclosure with a getter, however at high bonding temperatures, non-evaporable getters can become activated and/or saturated due to the material outgassing. This prevents the getters from lowering and/or maintaining the vacuum pressure at < 1E-6 mbar in the MVC vacuum enclosure over an extended period due to finite sorption capacity of the getters.

An ideal vacuum cell is fabricated in the following way: Materials that have been processed to possess vacuum cavities containing non-evaporable getters along with their lids are baked at low baking temperature at for example 100C to 350C for an extended period of time (~ one hour to a plurality of days) to remove Hydrogen, Helium, and noble gasses that may be dissolved within or adsorbed to material surfaces. Low Helium permeation materials are bonded together at low temperature (room temperature to 250C) in a high vacuum (one millibar to 10E-12 millibar) vacuum environment. The non-evaporable getter is activated inside of a sealed vacuum chamber using either heat from an oven or if optically transparent then a high-power optical source to heat and activate the non-evaporable getters. Optionally, chemically active getters such as alkali atoms can be used for additional vacuum pumping.

Another problem of high temperature bonding is that it requires assembling only materials with similar coefficients of thermal expansion. An exception to this is indium bonding due to the strength and malleability of indium. However, indium bonding does not provide a leak rate low enough to maintain vacuum efficiently in a vacuum enclosure. A high leak rate necessitates either an active vacuum pump, or limits the lifetime and base pressure of a MVC.

In the past, the high bonding temperature has limited the bonding to between materials with similar coefficient of thermal expansion. This has resulted in specialty glasses being designed such as the material commercially known as „Hoya SD2 Aluminosilicate“ that matches the coefficient of thermal expansion of silicon. However, glass materials are prone to helium permeation, thus limiting the ambient pressure to ~5 millibar (the partial pressure of helium in atmosphere). The realization of MVCs that can use materials of different Coefficients of Thermal Expansion (CTE) would open up the possibility of using low Helium permeation materials, such as single crystalline sapphire, to form vacuum cells.

The prior art comprises the following references:

Karlen, Sylvain, Jacques Haesler, Thomas Overstolz, Giovanni Bergonzi, and Steve Lecomte. 2020. “Sealing of MEMS Atomic Vapor Cells Using Cu-Cu Thermocompression Bonding.” Journal of Microelectromechanical Systems 29 (1): 95–99. https://doi.org/10.1109/JMEMS.2019.2949349.

Wang, Yiqun, Yaning Wu, Xianhai Xia, Minwei Jiang, Yu Han, Limin Zou, and Peng Jin. 2019. “Micro-Fabricated Alkali Vapor Cells Sealed at Low Temperature Using Asymmetric Au–In Transient Liquid Phase (TLP) Bonding.” Japanese Journal of Applied Physics 58 (SD): SDDL03. https://doi.org/10.7567/1347-4065/ab0ac9.

Pétremand, Y., C. Schori, R. Straessle, G. Mileti, N. de Rooij, and P. Thomann. 2010. “Low Temperature Indium-Based Sealing of Microfabricated Alkali Cells for Chip Scale Atomic Clocks.” In EFTF-2010 24th European Frequency and Time Forum, 1–3. https://doi.org/10.1109/EFTF.2010.6533683.

Guo, Ping, Hongling Meng, Lin Dan, and Jianye Zhao. 2022. “Low Power Consumption Physics Package for Chip-Scale Atomic Clock through Gold-Tin Eutectic Bonding.” Microsystem Technologies 28 (7): 1601–6. https://doi.org/10.1007/s00542-022-05283-y.

Wang, Xiaojing, Simon J. Bleiker, Mikael Antelius, Göran Stemme, and Frank Niklaus. 2017. “Wafer-Level Vacuum Packaging Enabled by Plastic Deformation and Low-Temperature Welding of Copper Sealing Rings With a Small Footprint.” Journal of Microelectromechanical Systems 26 (2): 357–65. https://doi.org/10.1109/JMEMS.2017.2654510.

Du, Lin, and Mark G. Allen. 2019. “CMOS Compatible Hermetic Packages Based on Localized Fusion Bonding of Fused Silica.” Journal of Microelectromechanical Systems 28 (4): 656–65. https://doi.org/10.1109/JMEMS.2019.2913533.

Sekiguchi, Naota, Takumi Sato, Kiyoshi Ishikawa, and Atsushi Hatakeyama. 2018. “Spectroscopic Study of a Diffusion-Bonded Sapphire Cell for Hot Metal Vapors.” Applied Optics 57 (1): 52–56. https://doi.org/10.1364/AO.57.000052.

Edinger, Pierre, Gaehun Jo, Chris Phong Van Nguyen, Alain Yuji Takabayashi, Carlos Errando-Herranz, Cleitus Antony, Giuseppe Talli, et al. 2023. “Vacuum-Sealed Silicon Photonic MEMS Tunable Ring Resonator with an Independent Control over Coupling and Phase.” Optics Express 31 (4): 6540–51. https://doi.org/10.1364/OE.480219.

Jo, Gaehun, Pierre Edinger, Simon J. Bleiker, Xiaojing Wang, Alain Yuji Takabayashi, Hamed Sattari, Niels Quack, et al. 2022. “Wafer-Level Hermetically Sealed Silicon Photonic MEMS.” Photonics Research 10 (2): A14–21. https://doi.org/10.1364/PRJ.441215.

Quack, Niels, Alain Yuji Takabayashi, Hamed Sattari, Pierre Edinger, Gaehun Jo, Simon J. Bleiker, Carlos Errando-Herranz, et al. 2023. “Integrated Silicon Photonic MEMS.” Microsystems & Nanoengineering 9 (1): 1–22. https://doi.org/10.1038/s41378-023-00498-z.

There exists a need for a MVC having a vacuum enclosure formed of at least two materials having different CTEs. U.S. Application No. 18/904886 (’886) provides for manufacturing such a vacuum enclosure, using a knife-edge hard metal wall pressed into a soft metal seal layer that allow forming a low-temperature compression bond. However, ’886 does not address the issue of shearing forces damaging the die or substrate to which the knife-edge hard metal wall is attached to when/if the knifes fully penetrate the compliant layer.

### SUMMARY

Embodiments of this presentation comprise a MVC with a vacuum enclosure that is formed using two elements having substantially different CTEs, as well as a method for manufacturing same.

Embodiments of this presentation comprise notably a MVC with high-vacuum cavities, where a first portion of the cavity is made of a material out of which it is easy to manufacture a MVC, such as Si, and where a second portion of the cavity is made out of a crystalline material with low helium permeation, even though the CTEs of these two materials are substantially different. In this presentation, “substantially different” CTEs means CTEs having a ratio of at least 5; preferably 7; preferably 10; preferably 20; preferably larger than 20.

Embodiments of this presentation comprise a method for realizing low-leak rate hermetic bonds at low temperature (room temperature to 250C) between different materials such as silicon, sapphire, fused silica, GaN, silicon carbide or any other semiconductor or ceramic material.

Embodiments of this presentation comprise a method for reducing the gas load on non-evaporable getters during the material bonding process.

Embodiments of this presentation comprise a method for bonding different CTE materials together using metal.

Embodiments of this presentation comprise a method for extending the lifetime of MVCs by lowering the number of adsorbed molecules on the getters during the bonding process.

Embodiments of this presentation comprise a method for activating the getters after bonding.

Embodiments of this presentation comprise using a mechanical stop structure enabling brittle materials such as SiO2 to avoid shearing forces/breakage during bonding.

Embodiments of this presentation include a micro-vacuum cell comprising at least one vacuum enclosure with a lid of a first material and a base of a second material, the first and second material having a different coefficients of thermal expansion, where the vacuum enclosure is formed above a portion of the base; a cold weld compression seal attaches the lid to the base along a periphery of said portion of the base; wherein the cold weld compression seal comprises a peripheral knife-edge wall with a foot being attached to one of the lid and the base and a tip that penetrates seal layer arranged on the other of the lid and the base; and a stop structure, shorter than the knife edge wall, with a foot attached to the same surface as the knife-edge wall and a tip that forms a compression bond with the seal layer.

Embodiments of this presentation include a micro-vacuum cell comprising at least one vacuum enclosure, the vacuum enclosure comprising at least: a lid of a first material, the first material having a first coefficient of thermal expansion; a base of a second material, the second material having a second coefficient of thermal expansion, where the vacuum enclosure is formed above a portion of the base; and a cold weld compression seal attaching the lid to the base along a periphery of said portion of the base; wherein the cold weld compression seal comprises a peripheral knife-edge wall of a first harder metal having a foot and a tip, the foot being attached to a first surface of one of the lid and the base, said knife-edge wall being coated with a first softer metal, and the tip of the knife-edge wall penetrating a seal layer of a second softer metal, arranged on a second surface of the other of the lid and the base, forming a compression bond between the peripheral knife-edge wall and the seal layer; and wherein: the knife-edge wall has a first height in a first direction normal to the first surface; the seal layer has a second height in said first direction; and at least one stop structure having a third height in said first direction has a foot attached to the first surface and a tip that forms a compression bond with the seal layer, wherein the third height is smaller than the first height and the second height is larger than a difference of the first and third height.

According to embodiments of this presentation, the stop structure has a flat tip.

According to embodiments of this presentation, the stop structure has a knife edge structure, and the tip of the stop structure forms a compression bond with the seal layer comprises the tip of the knife-edge stop structure penetrating the seal layer.

According to embodiments of this presentation, the knife-edge stop structure is made of a second harder metal wall and is coated with a third softer metal.

According to embodiments of this presentation, the compression bond between the seal layer and the knife wall or stop structure is such that the seal layer does not contact the foot of the peripheral knife edge wall or the foot of the stop structure.

According to embodiments of this presentation, the peripheral knife-edge wall comprises a first plurality of main wall segments, where each main wall segment forms a portion of a knife-edge enclosure wall of a different one of a first purality of buffer cells, each buffer cell knife-edge enclosure wall having an enclosure wall foot attached to said first surface around a buffer area and an enclosure wall tip forming a compression bond with the seal layer; wherein each buffer cell knife-edge enclosure wall may share a common portion with an enclosure wall of at least one neighboring buffer cell; and wherein each buffer cell may comprise a stop structure having a foot attached to the buffer area and a tip that forms a compression bond with the seal layer. The buffer cells of the first plurality of buffer cells may all have a same shape and a same size, or they can have different shapes and/or sizes.

According to embodiments of this presentation, when buffer cells are arranged around the micro-vacuum cell as detailed above, the stop structures in the micro-vacuum cell and the buffer cells can be optional.

According to embodiments of this presentation, the micro-vacuum cell further comprises a second plurality of buffer cells having each a same structure as a buffer cell of the first plurality of buffer cels, but the enclosure wall of each buffer cell of the second plurality of buffer cells shares no common portion with the first plurality of main wall segments of the peripheral knife-edge wall. The buffer cells of the second plurality of buffer cells may all have a same shape and a same size, or they can have different shapes and/or sizes.

According to embodiments of this presentation, one of the first and second coefficients of thermal expansion is at least five times larger than the other of the first and second coefficients of thermal expansion; and the pressure in the vacuum enclosure is smaller than an atmosphere.

According to embodiments of this presentation, said portion of the base comprises a recess, said recess forming part of the vacuum enclosure.

According to embodiments of this presentation, a getter is arranged on an inside portion of the vacuum enclosure.

According to embodiments of this presentation, at least one of the lid and the base is transparent to a light wavelength, wherein the getter can be activated by said light wavelength.

According to embodiments of this presentation, a micro-electromechanical structure is arranged in the vacuum enclosure.

According to embodiments of this presentation, one of the first and second coefficients of thermal expansion is at least ten times larger than the other of the first and second coefficients of thermal expansion; or one of the first and second coefficients of thermal expansion is at least twenty times larger than the other of the first and second coefficients of thermal expansion.

According to embodiments of this presentation, the pressure in the vacuum enclosure is smaller than a millitorr.

According to embodiments of this presentation, the first and second harder metals are titanium and the first, second and third softer metals are gold or aluminum or copper.

According to embodiments of this presentation, the materials of the lid and base are selected among silicon, glass (lime glass or fused silica), sapphire, alumina, SiC, AlN, GaAs, GaN and any other semiconductor or ceramic substrate.

Other embodiments of this presentation comprise a method of manufacturing a micro-vacuum cell comprising at least one vacuum enclosure, the method comprising: providing a lid of a first material, the first material having a first coefficient of thermal expansion; providing a base of a second material, the second material having a second coefficient of thermal expansion, where the vacuum enclosure is to be formed above a portion of the base; forming around said portion of the base a first part of a cold weld compression seal, and forming on a surface of the lid a corresponding second part of said cold weld compression seal; baking the lid and the base under vacuum for a predetermined time; without breaking the vacuum, letting the lid and the base cool down, then aligning the first and second parts of the cold weld compression seal and pressing the lid and the base together until a predetermined pressure is reached; wherein said first and second parts of the cold weld compression seal comprise each one of a peripheral knife-edge wall and a seal layer; the peripheral knife-edge wall being made of a first harder metal having a foot and a tip, the foot being attached to a first surface of one of the lid and the base, said knife-edge wall being coated with a first softer metal, such that the tip of the knife-edge wall penetrates the seal layer, made of a second softer metal and arranged on a second surface of the other of the lid and the base, and forms a compression bond with the seal layer when the lid and the base are pressed together until the predetermined pressure is reached; and wherein: the knife-edge wall has a first height in a first direction normal to the first surface; the seal layer has a second height in said first direction; and at least one stop structure having a third height in said first direction has a foot attached to the first surface and a tip that forms a compression bond with the seal layer when the lid and the base are pressed together until the predetermined pressure is reached, wherein the third height is smaller than the first height and the second height is larger than a difference of the first and third height.

According to embodiments of this presentation, the stop structure has a flat tip.

According to embodiments of this presentation, the stop structure has a knife edge structure, and the tip of the stop structure forms a compression bond with the seal layer comprises the tip of the knife-edge stop structure penetrating the seal layer.

According to embodiments of this presentation, the knife-edge stop structure is made of a second harder metal wall and is coated with a third softer metal.

According to embodiments of this presentation, the seal layer does not contact the foot of the peripheral knife edge wall or the foot of the knife-edge stop structure when the lid and the base are pressed together until the predetermined pressure is reached.

According to embodiments of this presentation, the peripheral knife-edge wall comprises a first plurality of main wall segments, where each main wall segment forms a portion of a knife-edge enclosure wall of a different one of a first purality of buffer cells, each buffer cell knife-edge enclosure wall having an enclosure wall foot attached to said first surface around a buffer area and an enclosure wall tip forming a compression bond with the seal layer when the lid and the base are pressed together until the predetermined pressure is reached; wherein the enclosure wall of each buffer cell may share a common portion with an enclosure wall of at least one neighboring buffer cell; and wherein each buffer cell may comprise a stop structure having a foot attached to the buffer area and a tip that forms a compression bond with the seal layer.

According to embodiments of this presentation, the method further comprises forming a second plurality of buffer cells having each a same structure as a buffer cell of the first plurality of buffer cels, but wherein the enclosure wall of each buffer cell of the second plurality of buffer cells shares no common portion with the first plurality of main wall segments of the peripheral knife-edge wall.

According to embodiments of this presentation, one of the first and second coefficients of thermal expansion is at least five (5) times larger than the other of the first and second coefficients of thermal expansion; and the pressure in the vacuum enclosure is smaller than an atmosphere.

According to embodiments of this presentation, the method further comprises forming a recess in said portion of the base, such that said recess forms part of the vacuum enclosure.

According to embodiments of this presentation, the method further comprises arranging a getter on an inside portion of the vacuum enclosure.

According to embodiments of this presentation, at least one of the lid and the base is transparent to a light wavelength, the method comprising activating the getter using said light wavelength once the cold weld compression seal has been completed.

According to embodiments of this presentation, the method further comprises arranging a micro-electromechanical structure on said portion of the base before baking the base, so that said micro-electromechanical structure is arranged in the vacuum enclosure.

According to embodiments of this presentation, one of the first and second coefficients of thermal expansion is at least ten times larger than the other of the first and second coefficients of thermal expansion; or one of the first and second coefficients of thermal expansion is at least twenty times larger than the other of the first and second coefficients of thermal expansion.

According to embodiments of this presentation, the pressure in the vacuum enclosure is smaller than a millitorr.

According to embodiments of this presentation, the first and second harder metals are titanium and the first, second and third softer metals are gold or aluminum or copper.

According to embodiments of this presentation, the materials of the lid and base are selected among silicon, glass, sapphire and SiC.

Embodiments of this presentation include a method for making high-vacuum MEMS cells at low temperatures (room temperature to 250C) enabling the use of materials with different coefficient of thermal expansion and/or enabling the use all-crystalline materials with low helium permeation. This method further allows handling adverse shearing forces that crack low-strength substrates by adding a stopping struture.

Other embodiments of this presentation include a micro-vacuum cell comprising at least one vacuum enclosure, the vacuum enclosure comprising at least: a lid of a first material; a base of a second material, where the vacuum enclosure is formed above a portion of the base; and a thermocompression seal attaching the lid to the base along a periphery of said portion of the base; wherein the thermocompression seal comprises a peripheral knife-edge wall of a first harder metal having a foot and a tip, the foot being attached to a first surface of one of the lid and the base, said knife-edge wall being coated with a first softer metal, and the tip of the knife-edge wall penetrating a seal layer of a second softer metal, arranged on a second surface of the other of the lid and the base, forming a compression bond between the peripheral knife-edge wall and the seal layer; and wherein: the knife-edge wall has a first height in a first direction normal to the first surface; the seal layer has a second height in said first direction; and at least one stop structure having a third height in said first direction has a foot attached to the first surface and a tip that forms a compression bond with the seal layer, wherein the third height is smaller than the first height and the second height is larger than a difference of the first and third height.

According to embodiments of this presentation, the stop structure has a flat tip.

According to embodiments of this presentation, the stop structure has a knife edge structure, and the tip of the stop structure forming a compression bond with the seal layer comprises the tip of the knife-edge stop structure penetrating the seal layer.

Other embodiments of this presentation include a method of manufacturing a micro-vacuum cell comprising at least one vacuum enclosure, the method comprising: providing a lid of a first material; providing a base of a second material, where the vacuum enclosure is to be formed above a portion of the base; forming around said portion of the base a first part of a thermocompression seal, and forming on a surface of the lid a corresponding second part of said thermocompression seal; baking the lid and the base under vacuum for a predetermined time; without breaking the vacuum, letting the lid and the base cool down to a thermocompression temperature, then aligning the first and second parts of the thermocompression seal and pressing the lid and the base together until a predetermined pressure is reached; wherein said first and second parts of the thermocompression seal respectively comprise one of a peripheral knife-edge wall and a seal layer; the peripheral knife-edge wall being made of a first harder metal having a foot and a tip, the foot being attached to a first surface of one of the lid and the base, said knife-edge wall being coated with a first softer metal, such that the tip of the knife-edge wall penetrates the seal layer, made of a second softer metal and arranged on a second surface of the other of the lid and the base, and forms a compression bond with the seal layer when the lid and the base are pressed together until the predetermined pressure is reached; and wherein: the knife-edge wall has a first height in a first direction normal to the first surface; the seal layer has a second height in said first direction; and at least one stop structure having a third height in said first direction has a foot attached to the first surface and a tip that forms a compression bond with the seal layer when the lid and the base are pressed together until the predetermined pressure is reached, wherein the third height is smaller than the first height and the second height is larger than a difference of the first and third height.

### FIGURES

The above features will now be described in more details in relation with the following figures, wherein:

FIG. 1 illustrates a cross section of a MVC according to embodiments of this presentation.

FIG. 2 illustrates a cross section of a MVC according to other embodiments of this presentation.

FIGS. 3A-3H illustrate successive steps of manufacturing of the MVC of FIG. 1.

FIG. 4 illustrates a cross section of a MVC according to other embodiments of this presentation.

FIGS. 5A and 5B illustrate details of two embodiments of this presentation.

FIG. 6 is a picture showing a MVC with buffer cells according to embodiments of this presentation..

FIG. 7 is an isometric view of a detail of FIG. 6.

FIG. 8 is a flow chart illustrating a method according to embodiments of this presentation.

FIGS. 9 and 10 illustrate how a micro-vacuum cell according to this presentation can be diced after manufacturing.

### DETAILED DESCRIPTION

The following description is presented to enable one of ordinary skill in the art to make and use the teachings of this presentation and to incorporate them in the context of particular applications. Various modifications, as well as a variety of uses in different applications will be readily apparent to those skilled in the art, and the general principles defined herein may be applied to a wide range of embodiments. Thus, the present invention is not intended to be limited to the embodiments presented, but is to be accorded the widest scope consistent with the principles and novel features disclosed herein.

In the following detailed description, numerous specific details are set forth in order to provide a more thorough understanding of embodiments of this presentation. However, it will be apparent to one skilled in the art that such embodiments may be practiced without necessarily being limited to these specilic details.

All the features disclosed in this presentation, (including any accompanying claims, abstract, and drawings) may be replaced by alternative features serving the same, equivalent or similar purpose, unless expressly stated otherwise. Thus, unless expressly stated otherwise, each feature disclosed is one example only of a generic series of equivalent or similar features.

Furthermore, any element in a claim that does not explicitly state "means for" performing a specified function, or "step for" performing a specilic function, is not to be interpreted as a "means" or "step" clause as specified in 35 U.S.C. Section 112(f). In particular, the use of "step of' or "act of' in the claims herein is not intended to invoke the provisions of 35 U.S.C. 112, Paragraph 6 (Pre-AIA).

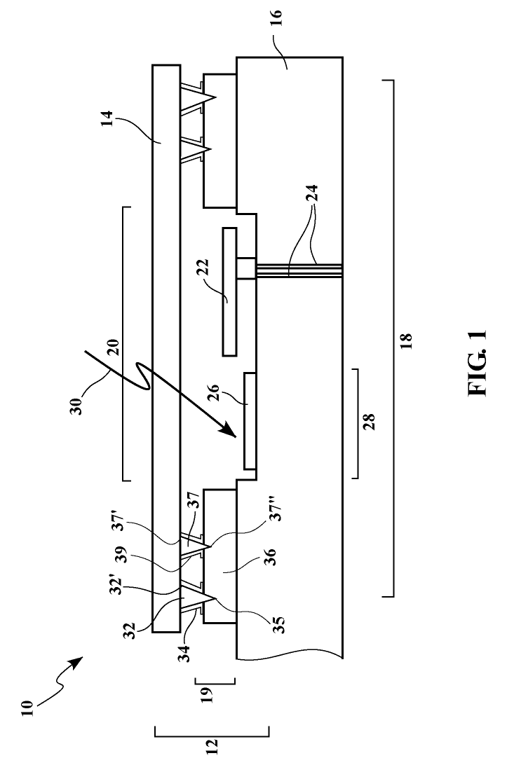

FIG. 1 illustrates a Micro-Vacuum Cell 10, comprising at least one vacuum enclosure 12. The vacuum enclosure 12 comprises at least: a lid 14 of a first material, the first material having a first coefficient of thermal expansion (CTE); a base 16 of a second material, the second material having a second coefficient of thermal expansion, wherein the vacuum enclosure is formed above a portion 18 of the base 16; and a cold weld compression seal 19 attaching the lid 14 to the base 16 along a periphery of said portion 18 of the base. According to embodiments of this presentation, the material of the lid 14 and the material of the base 16 may have a CTE ratio of at least 5; preferably 7; preferably 10; preferably 20; preferably larger than 20; and the pressure in the vacuum enclosure is smaller than an atmosphere; preferably smaller than a milliTorr, preferably smaller than a microTorr, and preferably smaller than 1E-12 Torr ( UHV).

According to embodiments of this presentation, the portion 18 of the base comprises a recess 20. The recess 20 forms part of the vacuum enclosure 12 and it provides room for arranging a moving part (or micro-electromechanical structure) 22 in the enclosure 12. Moving part 22 can comprise one or more crystal oscillators, but it can comprise any of one or more micro-mirrors or mechanical oscillators or gravity sensors. As illustrated in FIG. 1, Micro-Vacuum Cell 10 can comprise electrical connections 24 to the moving part 22. The electrical connections 24 are preferably coupled to a control circuit (not illustrated) integrated in base 16. Electrical connections 24 can comprise vias and they are provided such that no leaking of the vacuum of enclosure 12 is due to the structure of these connections.

According to embodiments of this presentation, a getter 26 is arranged on an inside portion 28 of the vacuum enclosure 12, for example of the portion 18 of the base 16. Getter 26 can be a layer of a getter material sputtered on inside portion 28 of enclosure 12. According to embodiments of this presentation, at least one of the lid 14 and the base 16 is transparent to a light having a predetermined wavelength, such that the getter can be activated by a beam 30 of said light. Alternatively, a heating circuit (not shown) can be arranged under the getter for activation.

According to embodiments of this presentation, the cold weld compression seal 19 comprises a peripheral knife-edge wall 32 of a harder metal having a foot 32’ attached to one of the lid 14 and the base 16 (to the lid 14 in FIG. 1), said knife-edge wall 32 being coated with a first softer metal layer 34 and having a tip 35 penetrating a seal layer 36 of a second softer metal, arranged on the other of the lid and the base (arranged on the periphery of the portion 18 of the base in FIG. 1) and forming a compression bond between the peripheral knife-edge wall 32 and the seal layer 36. The first and second softer metals can be a same softer metal or they can be different softer metals. According to embodiments of this presentation, the harder metal is titanium and the softer metal is gold or aluminum or copper. Other metal combinations include Ti/Cu, Ti/Pd, Ti/Ag, Ti/Al. As illustrated in FIG. 1, a portion of the first softer metal layer 34 coating the knife-edge wall 32 can be deformed when the tip 35 of the knife-edge wall 32 penetrates the seal layer 36, and can form a part of the compression bond with the seal layer 36.

According to embodiments of this presentation, the knife-edge wall 32 has a first height in a first direction normal to the first surface (i.e. vertical direction in FIG. 1), the seal layer 36 has a second height in said first direction. According to a preferred embodiment, the second height is larger than the first height. The cold weld compression seal 19 further comprises at least one stop structure 37, having a third height in said first direction, having a foot 37’ attached to the first surface and a tip 37” that forms a compression bond with the seal layer 36, wherein the third height is smaller than the first height and the second height is larger than a difference of the first and third height. As illustrated in FIG. 1, according to embodiments of this presentation the stop structure 37 has a knife edge structure, and the tip 37“ of the stop structure forms a compression bond with the seal layer 36 by having the tip 37“ of the knife-edge stop structure 37 penetrating the seal layer 36. According to embodiments of this presentation, the stop structure 37 is made of a second, harder metal (for example the same harder metal as the first harder metal) and can be coated with a layer 39 of a third, softer, metal (for example the same as the first and second softer metals). As illustrated in FIG. 1, a portion of the softer metal layer 39 coating the knife-edge stop structure 37 can be deformed when the tip 37” of the knife-edge stop structure 37 penetrates the seal layer 36, and can form a part of the compression bond with the seal layer 36. Importantly, the knife edge stop structure 37 is arranged such that the seal layer 36 does not contact the foot 32’ of the peripheral knife edge wall 32 or the foot 37’ of the knife-edge stop structure 37. The Inventors have noted that preventing the seal layer from coming in contact with the foot of the knife edge wall of the compression seal 19 (in other words, the knife edge wall penetrating all the way into the seal layer) prevents the formation of cracks under the knife edge walls by smoothly altering the pressure force as the knife edge walls penetrate the seal layer. It is noted that further knife-edge stop structures (not shown in FIG. 1) can also be arranged, on the same side of knife-edge wall 32 as illustrated in FIG. 1, or on the other side of knife-edge wall 32. It is to be noted that the stop structure is illustrated as being close to the knife edge wall 32 in FIG. 1, but a stop structure can be arranged essentially at any distance of the knife edge wall 32 as long as it has the function detailed herebove.

According to embodiments of this presentation, the materials of the lid and base are selected among silicon, glass (lime glass or fused silica), sapphire, alumina, SiC, AlN, GaAs, GaN and any other semiconductor or ceramic substrate.

It is noted that FIG. 1 illustrates a structure where the wall 32 and stop structure 37 are arranged on the lid 14 and the seal layer 36 is arranged on the base 16 around recess 20, but embodiments of this presentation also provide for arranging the wall 32 and stop 37 on the base 16 around recess 20 and arranging the seal layer 36 on the lid 14. This advantageously allows covering an entire surface of the lid with seal layer 36, thus warranting a simple manufacturing.

It is to be noted that, according to other embodiments of this presentation, cold weld compression seal 19 can be replaced by a thermocompression seal 19, having a same structure as cold weld compression seal 19 but where the lid 14 and base 16 are pressed together at a thermocompression temperature (higher than 250C) rather than at a low temperature to form the seal with a plasticly deformed thermocompression bond. In such embodiments, it is preferable that the lid 14 and base 16 be of a same material or of materials having similar CTEs. It is also preferable that the getter material, if any is present, not be activable at the thermocompression temperature. The structures and manufacturing processes are otherwise identical.

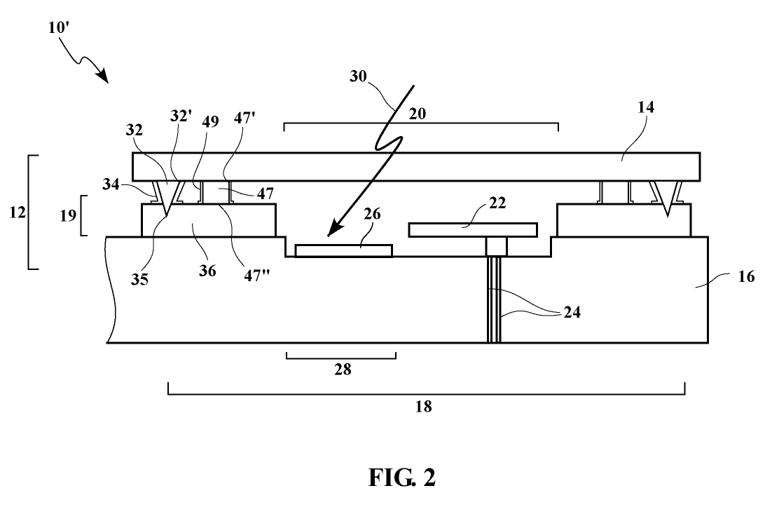

FIG. 2 illustrates a Micro-Vacuum Cell 10’, essentially identical to the Micro-Vacuum Cell 10 of FIG. 1, with the difference that instead of comprising the knife edge stop structure 37 of FIG. 1, the cold weld compression seal 19 comprises at least one stop structure 47, having a third height in said first direction, having a foot 47’ attached to the first surface and a tip 47” that forms a compression bond with the seal layer 36, wherein the third height is smaller than the first height and the second height is larger than a difference of the first and third height. As illustrated in FIG. 2, according to embodiments of this presentation the stop structure 47 has a flat tip, and the tip 47“ of the stop structure forms a compression bond with the seal layer 36 by being pressed against it. According to embodiments of this presentation, the stop structure 47 is made of a second, harder metal (for example the same harder metal as the first harder metal) and can be coated with a layer 49 of a third, softer, metal (for example the same as the first and second softer metals). As illustrated in FIG. 2, a portion of the softer metal layer 49 coating the tip 47” of the stop structure 47 can be deformed when the tip 47” of the stop structure 47 is pressed against the seal layer 36, and can form a part of the compression bond with the seal layer 36. Importantly, the stop structure 47 is arranged such that the seal layer 36 does not contact the foot 32’ of the peripheral knife edge wall 32 or the foot 47’ of the stop structure 47. The Inventors have noted that preventing the seal layer from coming in contact with the foot of the knife edge wall of the compression seal 19 prevents the formation of cracks under the knife edge walls by lowering the cutting pressure applied to the knife edge wall below a yield strength of the seal layer.

According to embodiments of this presentation, the materials of the lid and base are selected among silicon, glass (lime glass or fused silica), sapphire, alumina, SiC, AlN, GaAs, GaN and any other semiconductor or ceramic substrate.

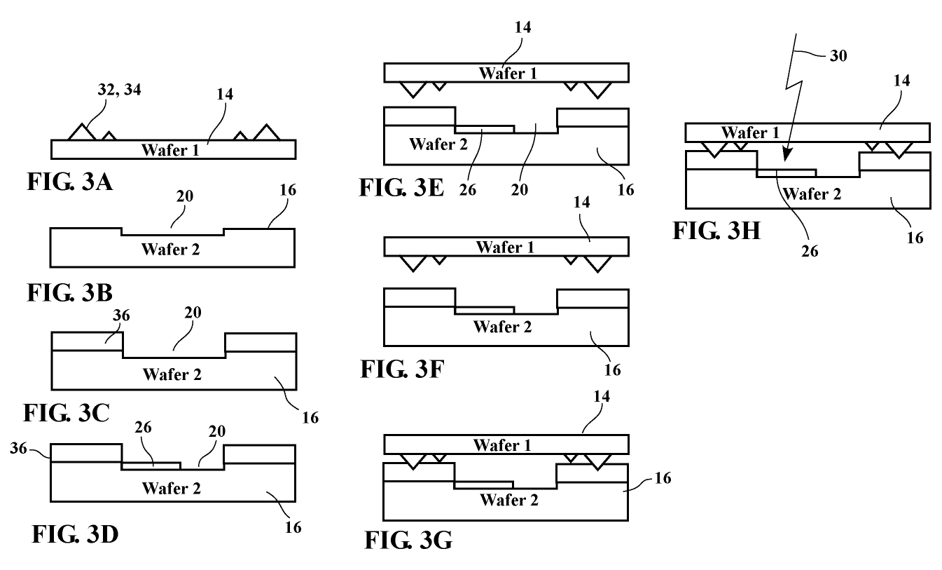

FIGS. 3A-3H illustrate successive steps of manufacturing of the Micro-Vacuum Cell 10 of FIG. 1. In FIG. 3A, lid 14 with the coated peripheral knife-edge wall 32, 34 is provided. By “peripheral”, it is meant that the wall completely encircles an area of the lid, or is arranged on a periphery of said area. Coated knife-edge stop 37, 39 can be arranged besides the knife edge wall 32 and may also define a peripheral structure. Knife-edge wall 32, 34 and knife edge stop 37, 39 can both be manufactured using photolithography manufacturing processes.

The width of the feet of the knife-edge wall 32 and knife-edge stop 37, as well as their heights can be of the order of a few micrometers. The wall 32 and stop 37 can be made of titanium. The wall 32 and stop 37 can each be capped by a layer (34, 39) of softer metal, for example gold or aluminum or copper, for example having a thickness of between 5nm to 5 microns. All metals can be deposited with e-beam evaporation and a photoresist process.

In FIG. 3B, base 16 having recess 20 is provided and in FIG. 3C, seal layer 36 is added on a periphery of recess 20. Moving part 22 can be arranged in recess 20 at this stage, but is not illustrated for clarity. In FIG. 3D, getter 26 is formed in a portion of recess 20. The recess can be formed with wet etching, dry-etching, or machining. The seal layer 36 can have a thickness of the order of one or more micrometers; for example of gold or aluminum or copper; it can be made using e-beam evaporation and a photoresist process.

In FIG. 3E, both the lid 14 and the base 16 are baked under vacuum for a predetermined time, to remove hydrogen, helium and noble gasses that are in the materials.

In FIG. 3F, without breaking the vacuum, the lid and the base are left to cool down to for example room temperature, before the first and second parts of the cold weld compression seal (the coated knife-edge wall) and the corresponding seal layer are aligned and in FIG. 3G they are pressed together until a predetermined pressure is reached, thus sealing the vacuum enclosure 12. Said predetermined pressure can for example be 300 MPa or more. The small feature size of the wall results in pressures at the knife-edge tip that are much greater than the deformation strength of the knife metal. This results in a cold-weld compression bond that is hermetic. The stop structure 37 is arranged such that the seal layer 36 does not come into contact with the foot 32’ of the peripheral knife edge wall 32 or the foot 37’ of the stop structure 37 when the predetermined pressure is applied. The Inventors have noted that preventing the seal layer from coming in contact with the foot of the knife edge wall 32 (or of the knife edge stop 37) prevents the formation of cracks under the knife edge wall (or under the knife edge stop).

In FIG. 3H, getter 26 is activated by a beam of light/radiation 30, for example from a high power laser, through lid 14. Activation of the getter 26 allows obtaining a higher level of vacuum in the enclosure 12 than at the time the enclosure 12 is sealed. A hot plate or other heating element can also be used to activate the getter.

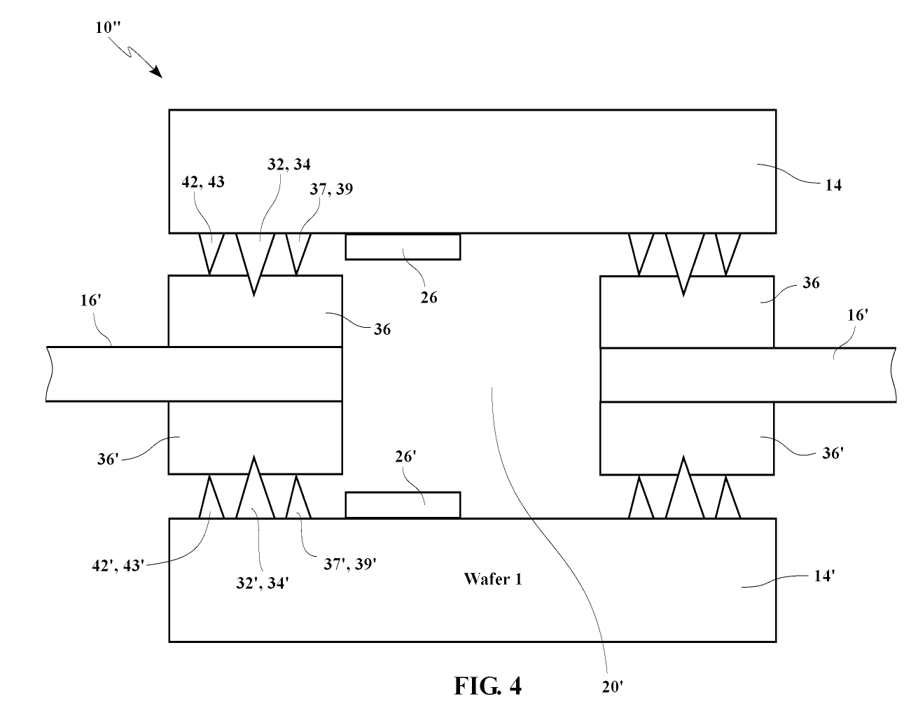

FIG. 4 illustrates a cross section of a MVC 10” according to other embodiments of this presentation, which is similar to the MVC 10 of FIG. 1, and wherein similar reference numbers relate to similar elements. However, MVC 10’’, instead of having a base 16 with a recess 20, has a base 16’ with a through-recess 20’ between a first main surface and a second main surface. In this embodiment, peripheral seal layer 36 is arranged on the first main surface of base 16’ on a periphery of recess 20’. Additionally, a second peripheral seal layer 36’ is arranged on the second main surface of base 16’ on a periphery of recess 20’. A second lid 14’, that can be of the same material as the first lid 14 or that can be of a different material, is attached to base 16’ by a second knife-edge peripheral wall 32’ attached to lid 14’, coated with a soft metal layer 34’, and pressed into said second peripheral seal layer 36’ in the same way as wall 32 for lid 14. A knife edge stop structure 37’, 39’, comparable to the knife edge stop structure 37, 39, is arranged besides knife-edge peripheral wall 32’ and has the same function as stop structure 37, 39 at the side of wall 32, 34. A getter 26 can be attached to lid 14 inside the vacuum enclosure comprising recess 20’. A getter 26’ can be attached to lid 14’ inside the vacuum enclosure comprising recess 20’. A getter (not illustrated) can also be attached to a wall of recess 20’. Moving part 22 (not illustrated) can be attached to one of lids 14, 14’ or to a wall of recess 20’. As outlined hereabove, according to embodiments of this presentation a further knife-edge stop structure (42, 43; 42’, 43’) identical in construction and function to the first knife-edge stop structure (37, 39; 37’, 39’) is arranged on the other side of knife-edge wall 32, respectively 32’ with respect to the first knife-edge stop structure (37, 39; 37’, 39’) and strengthens the compression bond while reducing the chance of developing cracks at the base of the knife edge wall.

Generally speaking, embodiments of this presentation comprise MVCs with vacuum enclosures having multilayer bonds that can comprise more than one base with a through-recess attached together, for example using cold-weld compression bonds.

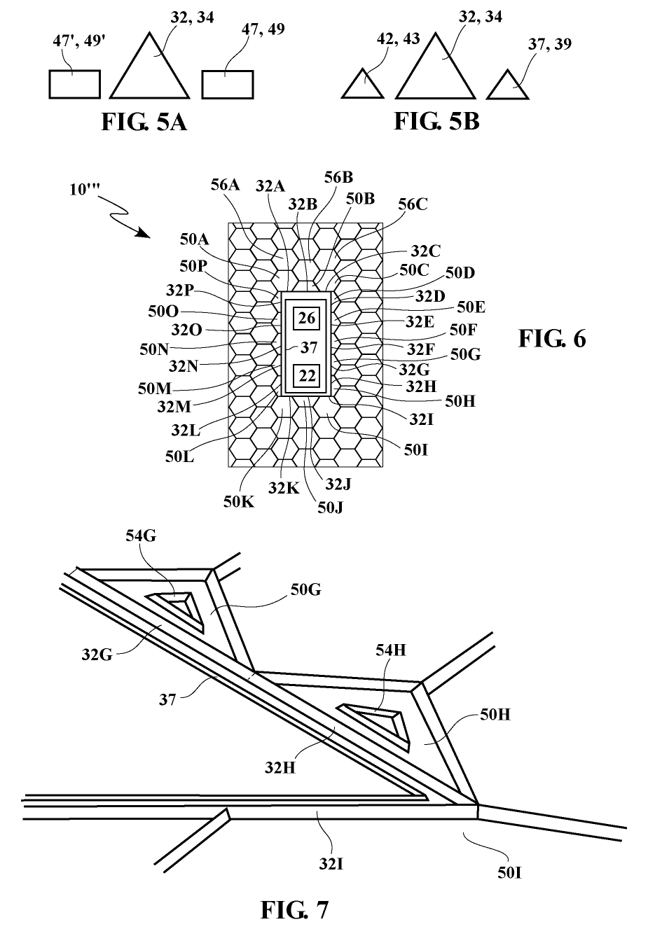

FIG. 5A is a picture of a cross section of a knife edge wall (32, 34) according to embodiments of this presentation close to the embodiment illustrated in FIG. 2, surrounded by two flat-tipped stop structures 47, 49 and 47’, 49’ that are provided for being attached to the first surface similarly to what is described in relation to FIG. 2. A method for fabricating a vacuum cell according to embodiments of this presentation that use the stop structure of FIG. 5A comprises:

Step 1a: Making patterned 1 to 10 um sized knife-edge features out of 1 to 10 um of Titanium and then capping the Titanium with 5 nm to 5 um of Cu or Al or gold on a flat wafer (wafer or chip 1).

Step 1b: Making patterned ~um sized towers/pillars of smaller than the knife-edge features in Titanium and then capping the Titanium the same way as the knife-edge features.

Step 2: Patterning a recess in wafer (or chip) 2 to be used as a vacuum cell. This can be done with wet etching, dry-etching, or machining.

Step 3: Patterning wafer (or chip) 2 to have thick 1 to 10 um sized soft metal seal layer (Cu, Al or Au).

Step 4: Depositing, or placing in by hand a non-evaporable getter material.

Step 5: Outgassing bake of both wafer (or chip) 1 and wafer (or chip) 2 to remove hydrogen, helium and noble gasses that are in the materials.

Step 6: Aligning the features on wafer (or chip) 1 to wafer (or chip) 2.

Step 7: Using a high force wafer bonder to bond the wafers together. The small feature size results in pressures at the knife-edge tip that are much greater than the deformation strength of the knife metal ~ 300MPa. This results in a cold-weld compression bond that is hermetic.

Step 8: Activating the encosed getters in the hermetically bonded wafers with thermal energy provided by a hot plate, high power laser, or other heating element.

Step 2-7 can be repeated many times to create multilayer bonds. See for instance the FIG. 4, which shows the bonding of three wafers instead of two.

FIG. 5B is a picture of a cross section of a knife edge wall (32, 34) according to embodiments of this presentation close to the embodiment illustrated in FIG. 1, surrounded by two knife-edge stop structures 37, 39 and 42, 43 that are provided for being attached to the first surface similarly to what is described in relation to FIG. 1. A method for fabricating a vacuum cell according to embodiments of this presentation that use the stop structure of FIG. 5B comprises:

Step 1a:: Making patterned 1 to 10 um sized knife-edge features out of 1 to 10 um of Titanium and then capping the Titanium with 5 nm to 5 um of Cu or Al or gold on a flat wafer (wafer or chip 1). Using photolithography, knifes of different height can be patterned. A mask enabling this can be used. All metals are deposited with e-beam evaporation and a photoresist process.

Step 2: Patterning a recess in wafer (or chip) 2 to be used as a vacuum cell. This can be done with wet etching, dry-etching, or machining.

Step 3: Patterning wafer (or chip) 2 to have thick 1 um to 10 um sized gold seal.

Step 4: Depositing, or placing in by hand a non-evaporable getter material.

Step 5: Outgassing bake at 100C to 350C to remove hydrogen, helium and noble gasses that are in the materials.

Step 6: Aligning the features on wafer (or chip) 1 to wafer (or chip) 2.

Step 7: using a high force wafer bonder to bond the wafers together. The small feature size results in pressures at the knife-edge tip that are much greater than the deformation strength of the knife metal ~ 300MPa. This results in a cold-weld compression bond that is hermetic.

Step 8: Activating the enclosed getters of the hermetically bonded wafers with thermal energy provided by a heating element.

FIG. 6 is a top view of a micro-vacuum cell 10’” according to embodiments of this presentation, that is similar to the vacuum cell 10 of FIG. 1, except that the peripheral knife-edge wall 32 has its foot attached to the base 16, and is provided to form a compression seal with a seal layer (not shown) on an inside surface of a lid (also not shown). Another difference is that that the continiuous peripheral knife-edge wall 32 of cell 10’” can be considered as a series of first plurality of main wall segments (32A, 32B, 32C, 32D, etc… to 32P as illustrated) connected end to end to form the closed wall 32 around getter 26 and payload / moving part 22. Further, according to the illustrated embodiment, each main wall segment (32A, 32B, 32D, 32D, … 32P) forms a portion of a knife-edge enclosure wall of one of a first plurality of buffer cells (50A, 50B, 50C, 50D, … 50P). Each knife-edge enclosure wall of the buffer cells (50A, 50B, 50C, 50D, … 50P) has an enclosure wall foot attached to the first surface of base 16 around a buffer area. Each knife-edge enclosure wall of a buffer cell (50A, 50B, 50C, 50D, … 50P) can have a same cross section and height as knife-edge wall 32, and has a wall tip arranged to form a compression bond with the seal layer 36 on the lid (not shown in FIG. 6) when the lid is pressed onto the base. As illustrated, the enclosure wall of each buffer cell (50A, 50B, 50C, 50D, … 50P) may share a common portion of wall with an enclosure wall of at least one neighboring buffer cell.

According to further embodiments of this presentation, the micro-vacuum cell 10’“ can also comprise a second plurality of buffer cells (56A, 56B, 56C shown in FIG. 6) having each essentially a same structure as a buffer cell of the first plurality of buffer cells (50A, 50B, 50C, 50D, etc…), but wherein the enclosure wall of each buffer cell of the second plurality of buffer cells (56A, 56B, 56C illustrated) comprises none of the main wall segments (32A, 32B, 32C, 32D, etc...) of the peripheral knife-edge wall 32.

A technical advantage of providing buffer cells around the peripheral knife wall is to reduce potential leaks into the vacuum enclosure formed by the peripheral knife wall. Advantageously, a structure as illustrated in FIG. 6 can safely be diced by cutting through the second plurality of buffer cells. According to embodiments, the buffer cells can have identical sizes or shapes, or they can have different sizes and shapes. In FIG. 6, most buffer cells are identical and they form together a beehive structure, except for the first plurality of buffer cells (50A, 50B, 50C, 50D, … 50P), the shape of which is adapted to comprise one of the plurality of main wall segments (32A, 32B, 32C, 32D, etc...).

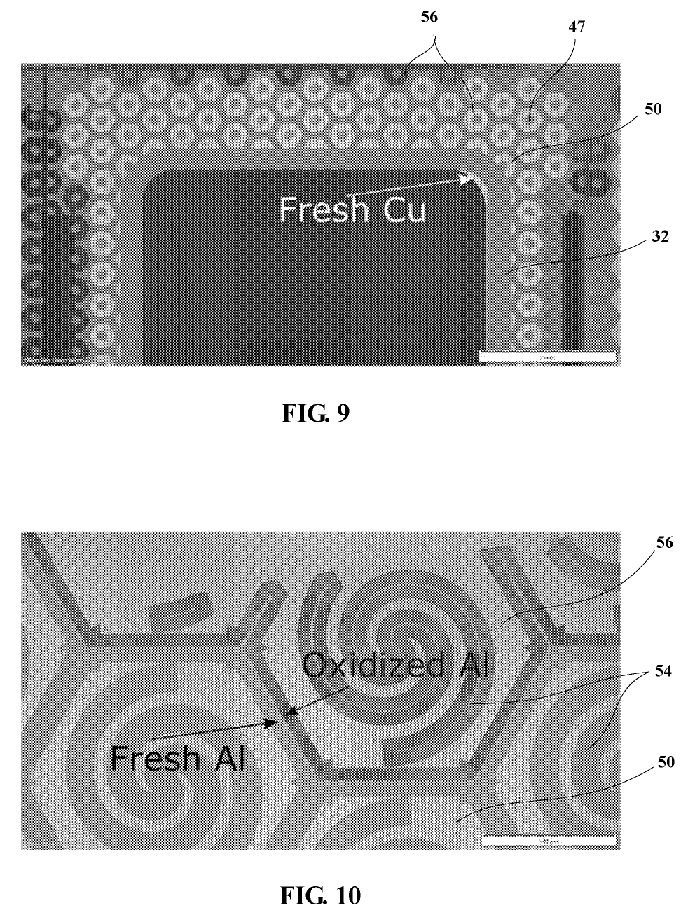

FIG. 7 illustrates an isometric view of a portion (lower right corner) of the knife edge wall 32 of FIG. 6, and shows in detail the knife edge enclosure walls of buffer cells 50G and 50H that respectively share the portions 32G and 32H of knife edge wall 32. As illustrated in FIG. 7, optionally, each buffer cell can comprise a stop structure (e.g. 54G, 54H illustrated) having a foot attached to the buffer area of the first surface and a tip arranged to form a compression bond with the seal layer of the lid (not shown in FIG. 6) when the lid is pressed onto the base. The stop structures (54G, 54H) arranged inside of the buffer cells (50G, 50H) are shown having a shape that somehow matches the shape of the knife edge enclosure walls of the buffer cells (50G, 50H). Alertnatively, the stop structures (54G, 54H) arranged inside of the buffer cells (50G, 50H) can have any desired shape; for example as illustrated in FIGS. 9 and 10 hereafter.

Stop structure 37 is shown inside of the peripheral knife-edge wall 32 along the peripheral knife-edge wall 32 but, as outlined above, stop structure 37 can alternatively be arranged at other positions with respect to the peripheral knife-edge wall 32, as outlined in relation to the previous figures.

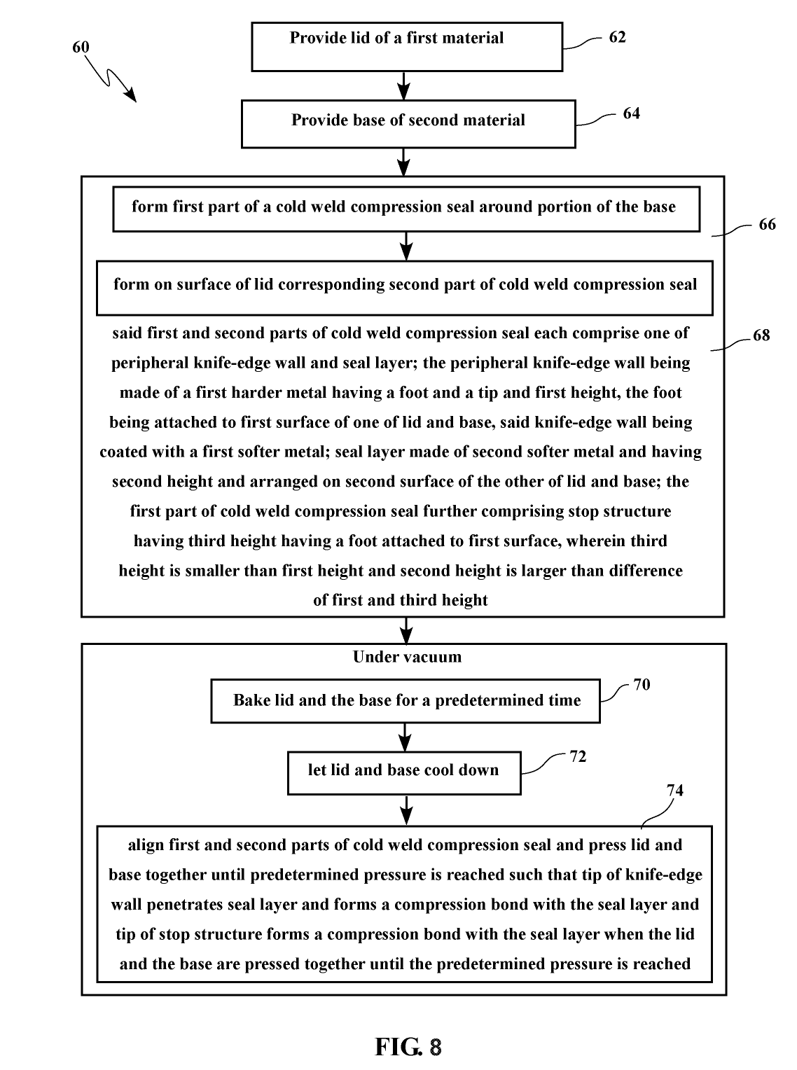

FIG. 8 is a flow chart illustrating a method 60 of manufacturing a micro-electromechanical systems apparatus according to embodiments of this presentation, the method comprising:

Providing 62 a lid of a first material, the first material having a first coefficient of thermal expansion.

Providing 64 a base of a second material, the second material having a second coefficient of thermal expansion, where the vacuum enclosure is to be formed above a portion of the base.

Forming 66 around said portion of the base a first part of a cold weld compression seal, and forming 68 on a surface of the lid a corresponding second part of said cold weld compression seal, wherein the first and second parts of the cold weld compression seal each comprise one of a peripheral knife-edge wall and a seal layer; the peripheral knife-edge wall being made of a first harder metal having a foot and a tip and first height, the foot being attached to first surface of one of lid and base, and said knife-edge wall being coated with a first softer metal; wherein the seal layer is made of second softer metal and has a second height and is arranged on second surface of the other of lid and base; the first part of the cold weld compression seal further comprising a stop structure having a third height and having a foot attached to the first surface, wherein the third height is smaller than the first height and the second height is larger than a difference of the first and the third height.

Baking 70 the lid and the base under vacuum for a predetermined time and, without breaking the vacuum, letting the lid and the base cool down 72, then aligning 74 the first and second parts of the cold weld compression seal and pressing them together until a predetermined pressure is reached and the cold weld compression seal sealingly assembles the lid to the base.

According to embodiments of this presentation, the material of the lid 14 and the material of the base 16 have a CTE ratio of at least 5; preferably 7; preferably 10; preferably 20; preferably larger than 20; and the pressure in the vacuum enclosure is smaller than an atmosphere; preferably smaller than 1 milltorr, preferably smaller than one microTorr, preferably smaller than 1E-12 Torr.

According to embodiments of this presentation, said providing 64 a base where the vacuum enclosure is to be formed above a portion of the base comprises forming a recess in said portion of the base, such that said recess forms part of the vacuum enclosure.

According to embodiments of this presentation, said providing 62 a lid and/or said providing 64 a base comprises arranging a getter on the lid or on the base such that the getter ends up on an inside portion of the vacuum enclosure.

According to embodiments of this presentation, said providing 62 a lid and/or said providing 64 a base comprises providing a lid and/or a base that is transparent to a light wavelength capable of activating the getter; the method further comprising activating the getter using said light wavelength once the cold weld compression seal has been completed.

According to embodiments of this presentation, said providing 62 a lid and/or said providing 64 a base comprises arranging a micro-electromechanical structure on the lid or on said portion of the base before baking the base and the lid, such that said micro-electromechanical structure ends up arranged in the vacuum enclosure.

In other words, according to embodiments of this presentation, a MVC having a vacuum encolosure is fabricated by: baking a base with a recess and (optionally) a non-evaporable getter in the recess, as well as a lid of a size corresponding to the recess, at low temperature for an extended period of time to remove hydrogen, helium, and noble gasses that may be dissolved within or adsorbed to material surfaces. The base and lid are preferably low helium permeation materials. The lid and the base recess respectively bear on their periphery first and second parts of a cold weld compression seal; the lid and the base are bonded together at a low temperature (room temperature to 250C) in a high vacuum <1E-6 Torr vacuum environment by pressing together the first and second parts of the cold weld compression seal.

In case a getter is in the recess, the getter is then activated inside the sealed vacuum enclosure using either heat from an oven or, if the lid or the base is optically transparent, a high-power optical source can be used to heat and activate the non-evaporable getters.

Optionally, chemically active getters such as alkali atoms can be used for additional vacuum pumping.

FIG. 9 is a picture of a portion of a micro-vacuum cell 10’’’according to embodiments of this presentation, having a sealed payload recess enclosed by a wall 32, surrounded by buffer cells comprised of first and second pluralities of buffer cells 50, 56 as described hereabove. The wafer was diced by cutting through the second plurality of buffer cells 56. Flat tip stop structures 47 are shown within most of the buffer cells 50, 56. The walls and stop structures in FIG. 9 were made of copper-coated titanium. One will appreciate that the walls or stops of the buffer cells 56 that have been cut through when separating the MVC 10’’’ from its manufacturing wafer, will quickly oxidize.

FIG. 10 is a detail picture of portions of buffer cells 56 of the second plurality of buffer cells as described hereabove. In case a plurality of micro-vacuum cells are manufactured on a same wafer, the micro-vacuum cells can be separated by cutting the wafer through the second plurality of buffer cells 56. Knife-edge stop structures 54 having a double spiral shape are shown within each of the buffer cells 56. The walls and stop structures in FIG. 10 were made of aluminum coated titanium. One will appreciate that the walls or stop structures of the buffer cells 56 that have been cut through when separating the micro-vacuum cells from each other, quickly oxidize.

Having now described the invention in accordance with the requirements of the patent statutes, those skilled in this art will understand how to make changes and modifications to the present invention to meet their specific requirements or conditions. Such changes and modifications may be made without departing from the scope and spirit of the invention as disclosed herein.

The foregoing Detailed Description of exemplary and preferred embodiments is presented for purposes of illustration and disclosure in accordance with the requirements of the law. It is not intended to be exhaustive nor to limit the invention to the precise form(s) described, but only to enable others skilled in the art to understand how the invention may be suited for a particular use or implementation. The possibility of modifications and variations will be apparent to practitioners skilled in the art. No limitation is intended by the description of exemplary embodiments which may have included tolerances, feature dimensions, specific operating conditions, engineering specifications, or the like, and which may vary between implementations or with changes to the state of the art, and no limitation should be implied therefrom.

Applicant has made this disclosure with respect to the current state of the art, but also contemplates advancements and that adaptations in the future may take into consideration of those advancements, namely in accordance with the then current state of the art. It is intended that the scope of the invention be defined by the Claims as written and equivalents as applicable. Reference to a claim element in the singular is not intended to mean "one and only one" unless explicitly so stated. Moreover, no element, component, nor method or process step in this disclosure is intended to be dedicated to the public regardless of whether the element, component, or step is explicitly recited in the Claims. No claim element herein is to be construed under the provisions of 35 U.S.C. Sec. 112(f), unless the element is expressly recited using the phrase "means for. . ." and no method or process step herein is to be construed under those provisions unless the step, or steps, are expressly recited using the phrase "comprising the step (s) of . . .. "

All elements, parts and steps described herein are preferably included. It is to be understood that any of these elements, parts and steps may be replaced by other elements, parts and steps or deleted altogether as will be obvious to those skilled in the art.

1. A micro-vacuum cell comprising at least one vacuum enclosure, the vacuum enclosure comprising:
a lid of a first material, the first material having a first coefficient of thermal expansion;
a base of a second material, the second material having a second coefficient of thermal expansion, where the vacuum enclosure is formed above a portion of the base; and
a cold weld compression seal attaching the lid to the base along a periphery of said portion of the base; wherein the cold weld compression seal comprises a peripheral knife-edge wall of a first harder metal having a foot and a tip, the foot being attached to a first surface of one of the lid and the base, said knife-edge wall being coated with a first softer metal, and the tip of the knife-edge wall penetrating a seal layer of a second softer metal, arranged on a second surface of the other of the lid and the base, forming a compression bond between the peripheral knife-edge wall and the seal layer; and wherein:
the knife-edge wall has a first height in a first direction normal to the first surface; the seal layer has a second height in said first direction; and at least one stop structure having a third height in said first direction has a foot attached to the first surface and a tip that forms a compression bond with the seal layer, wherein the third height is smaller than the first height and the second height is larger than a difference of the first and third height.

2. The micro-vacuum cell of claim 1, wherein the stop structure has a flat tip.

3. The micro-vacuum cell of claim 1, wherein the stop structure has a knife edge structure, and the tip of the stop structure forming a compression bond with the seal layer comprises the tip of the knife-edge stop structure penetrating the seal layer.

4. The micro-vacuum cell of claim 1, where the knife-edge stop structure is made of a second harder metal wall and is coated with a third softer metal.

5. The micro-vacuum cell of claim 1, where the peripheral knife-edge wall comprises a first plurality of main wall segments, where each main wall segment forms a portion of an enclosure wall of a different one of a first purality of buffer cells, the enclosure wall of each buffer cell being a knife-edge enclosure wall with an enclosure wall foot attached to said first surface around a buffer area and an enclosure wall tip forming a compression bond with the seal layer.

6. The micro-vacuum cell of claim 5, further comprising a second plurality of buffer cells having each a same structure as a buffer cell of the first plurality of buffer cels, but wherein the enclosure wall of each buffer cell of the second plurality of buffer cells shares no common portion with the first plurality of main wall segments of the peripheral knife-edge wall.

7. A method of manufacturing a micro-vacuum cell comprising at least one vacuum enclosure, the method comprising:
providing a lid of a first material, the first material having a first coefficient of thermal expansion;
providing a base of a second material, the second material having a second coefficient of thermal expansion, where the vacuum enclosure is to be formed above a portion of the base;
forming around said portion of the base a first part of a cold weld compression seal, and forming on a surface of the lid a corresponding second part of said cold weld compression seal;
baking the lid and the base under vacuum for a predetermined time;
without breaking the vacuum, letting the lid and the base cool down, then sligning the first and second parts of the cold weld compression seal and pressing the lid and the base together until a predetermined pressure is reached;
wherein said first and second parts of the cold weld compression seal respectively comprise one of a peripheral knife-edge wall and a seal layer; the peripheral knife-edge wall being made of a first harder metal having a foot and a tip, the foot being attached to a first surface of one of the lid and the base, said knife-edge wall being coated with a first softer metal, such that the tip of the knife-edge wall penetrates the seal layer, made of a second softer metal and arranged on a second surface of the other of the lid and the base, and forms a compression bond with the seal layer when the lid and the base are pressed together until the predetermined pressure is reached; and wherein:
the knife-edge wall has a first height in a first direction normal to the first surface;
the seal layer has a second height in said first direction; and
at least one stop structure having a third height in said first direction has a foot attached to the first surface and a tip that forms a compression bond with the seal layer when the lid and the base are pressed together until the predetermined pressure is reached, wherein the third height is smaller than the first height and the second height is larger than a difference of the first and third height.

8. The method of claim 7, where the stop structure has a flat tip.

9. The method of claim 8, where the stop structure has a knife edge structure, and wherein the tip of the stop structure forming a compression bond with the seal layer comprises the tip of the knife-edge stop structure penetrating the seal layer.

10. The method of claim 7, where the knife-edge stop structure is made of a second harder metal wall and is coated with a third softer metal.

11. The method of claim 7, where the the peripheral knife-edge wall comprises a first plurality of main wall segments, where each main wall segment forms a portion of an enclosure wall of a first purality of buffer cells, the enclosure wall of each buffer cell being a knife-edge enclosure wall having an enclosure wall foot attached to said first surface around a buffer area and an enclosure wall tip forming a compression bond with the seal layer when the lid and the base are pressed together until the predetermined pressure is reached.

12. The method of claim 7, further comprising forming a second plurality of buffer cells having each a same structure as a buffer cell of the first plurality of buffer cels, but wherein the enclosure wall of each buffer cell of the second plurality of buffer cells shares no common portion with the first plurality of main wall segments of the peripheral knife-edge wall.

13. The micro-vacuum cell of claim 1 or the method of claim 7, wherein one of the first and second coefficients of thermal expansion is at least five times larger than the other of the first and second coefficients of thermal expansion; and the pressure in the vacuum enclosure is smaller than an atmosphere.

14. The micro-vacuum cell of claim 1 or the method of claim 7, wherein the first and second harder metals are titanium and the first, second and third softer metals are gold or aluminum or copper.

15. The micro-vacuum cell of claim 1 or the method of claim 7, wherein the materials of the lid and base are selected among silicon, glass, sapphire and SiC.

16. A micro-vacuum cell comprising at least one vacuum enclosure, the vacuum enclosure comprising:
a lid of a first material;
a base of a second material, wherein the vacuum enclosure is formed above a portion of the base; and
a thermocompression seal attaching the lid to the base along a periphery of said portion of the base; wherein the thermocompression seal comprises a peripheral knife-edge wall of a first harder metal having a foot and a tip, the foot being attached to a first surface of one of the lid and the base, said knife-edge wall being coated with a first softer metal, and the tip of the knife-edge wall penetrating a seal layer of a second softer metal, arranged on a second surface of the other of the lid and the base, forming a compression bond between the peripheral knife-edge wall and the seal layer; and wherein:
the knife-edge wall has a first height in a first direction normal to the first surface; the seal layer has a second height in said first direction; and at least one stop structure having a third height in said first direction has a foot attached to the first surface and a tip that forms a compression bond with the seal layer, wherein the third height is smaller than the first height and the second height is larger than a difference of the first and third height.

17. The micro-vacuum cell of claim 16, wherein the stop structure has a flat tip.

18. The micro-vacuum cell of claim 16, wherein the stop structure has a knife edge structure, and the tip of the stop structure forming a compression bond with the seal layer comprises the tip of the knife-edge stop structure penetrating the seal layer.

19. A method of manufacturing a micro-vacuum cell comprising at least one vacuum enclosure, the method comprising:
providing a lid of a first material;
providing a base of a second material, wherein the vacuum enclosure is to be formed above a portion of the base;
forming around said portion of the base a first part of a thermocompression seal, and forming on a surface of the lid a corresponding second part of said thermocompression seal;
baking the lid and the base under vacuum for a predetermined time;
without breaking the vacuum, letting the lid and the base cool down to a thermocompression temperature, then aligning the first and second parts of the thermocompression seal and pressing the lid and the base together until a predetermined pressure is reached;
wherein said first and second parts of the thermocompression seal respectively comprise one of a peripheral knife-edge wall and a seal layer; the peripheral knife-edge wall being made of a first harder metal having a foot and a tip, the foot being attached to a first surface of one of the lid and the base, said knife-edge wall being coated with a first softer metal, such that the tip of the knife-edge wall penetrates the seal layer, made of a second softer metal and arranged on a second surface of the other of the lid and the base, and forms a compression bond with the seal layer when the lid and the base are pressed together until the predetermined pressure is reached; and wherein:
the knife-edge wall has a first height in a first direction normal to the first surface;
the seal layer has a second height in said first direction; and
at least one stop structure having a third height in said first direction has a foot attached to the first surface and a tip that forms a compression bond with the seal layer when the lid and the base are pressed together until the predetermined pressure is reached, wherein the third height is smaller than the first height and the second height is larger than a difference of the first and third height.
